(19) United States
(12) Patent Application Publication
(10) Pub. No.: US 2008/0082879 A1
(43) Pub. Date: Apr. 3, 2008

(54) JTAG boundary scan compliant testing architecture with full and partial disable

(76) Inventor: Amar Guettaf, Sunnyvale, CA (US)

Correspondence Address: FARJAMI & FARJAMI LLP, 26522 LA ALAMEDA AVENUE, SUITE 360, MISSION VIEJO, CA, 92691, US

(21) Appl. No.: 11/540,208

(22) Filed: Sep. 29, 2006

(51) Int. Cl. G01R 31/28

(52) U.S. Cl. 714/727

(57) ABSTRACT

A semiconductor device includes a JTAG boundary scan compliant testing architecture built into the semiconductor device, where the semiconductor device has a number of input points and output points. The JTAG boundary scan compliant testing architecture includes a TAP controller capable of receiving input test data, a test mode-select, and a test clock. In one embodiment, a full JTAG disable interface is utilized whereby the JTAG boundary scan compliant testing architecture allows an authorized user to prevent an unauthorized user from storing data into or reading data from input boundary scan registers and from reading data from output boundary scan registers. In another embodiment, a partial JTAG disable interface is utilized whereby an authorized user can prevent an unauthorized user from storing data into a pre-designated input boundary scan register, or from reading data from a pre-designated output boundary scan register.

### BACKGROUND OF THE INVENTION

1. Field of the Invention

The present invention is generally in the field of semiconductor devices. More specifically, the present invention is in the field of testing semiconductor devices.

2. Background Art

Advances in semiconductor device packaging and circuit board manufacturing have made it very difficult to test the circuit board and/or the semiconductor devices by physically accessing or probing circuit board interconnects that connect semiconductor devices on a circuit board. As a result, the Institute of Electrical and Electronic Engineers (“IEEE”) developed the IEEE 1149.1 standard, which includes a Joint Test Action Group (“JTAG”) boundary scan compliant testing architecture and provides means for, among other things, debugging and testing JTAG compliant devices on a circuit board without the need to physically probe the circuit board interconnects to access a particular device or a particular circuit board interconnect.

According to the IEEE 1149.1 standard a JTAG boundary scan compliant testing architecture is built into a JTAG compliant device and includes, among other things, a boundary scan register at each input and output, and a Test Access Port (TAP) controller for controlling the functionality of each boundary scan register. In one mode of operation of the JTAG boundary scan compliant testing architecture, an authorized user can store data in input boundary scan registers and read stored data from output boundary scan registers of the JTAG compliant device, permitting the authorized user to access the device's internal secure data, or assess and learn about the state and/or functionality of the JTAG complaint device.

Disadvantageously, unauthorized users may also access the device's internal secure data, or assess and learn about the state and/or functionality of the JTAG complaint device by, for example, storing and accessing data in the device's input boundary scan registers and/or by reading stored data from the device's output boundary scan registers. Thus there is a need in the art to effectively and efficiently prevent an unauthorized user from accessing the internal secure data, and from assessing and learning about the state and/or functionality of the JTAG complaint device.

### SUMMARY OF THE INVENTION

A JTAG boundary scan compliant testing architecture with full and partial disable, substantially as shown in and/or described in connection with at least one of the figures, and as set forth more completely in the claims.

### BRIEF DESCRIPTION OF THE DRAWINGS

FIG. 1 is a schematic diagram illustrating a semiconductor device utilizing a conventional JTAG boundary scan compliant testing architecture.

FIG. 2 is a schematic diagram illustrating one exemplary embodiment of the invention's JTAG boundary scan compliant testing architecture.

FIG. 3 is a schematic diagram illustrating another exemplary embodiment of the invention's JTAG boundary scan compliant testing architecture.

FIG. 4 is a schematic diagram illustrating yet another exemplary embodiment of the invention's JTAG boundary scan compliant testing architecture.

### DETAILED DESCRIPTION OF THE INVENTION

The present invention is directed to a JTAG boundary scan compliant testing architecture with full and partial disable capabilities. Although the invention is described with respect to specific embodiments, the principles of the invention, as defined by the claims appended herein, can obviously be applied beyond the specifically described embodiments of the invention described herein. Moreover, in the description of the present invention, certain details have been left out in order to not obscure the inventive aspects of the invention. The details left out are within the knowledge of a person of ordinary skill in the art.

The drawings in the present application and their accompanying detailed description are directed to merely exemplary embodiments of the invention. To maintain brevity, other embodiments of the invention which use the principles of the present invention are not specifically described in the present application and are not specifically illustrated by the present drawings.

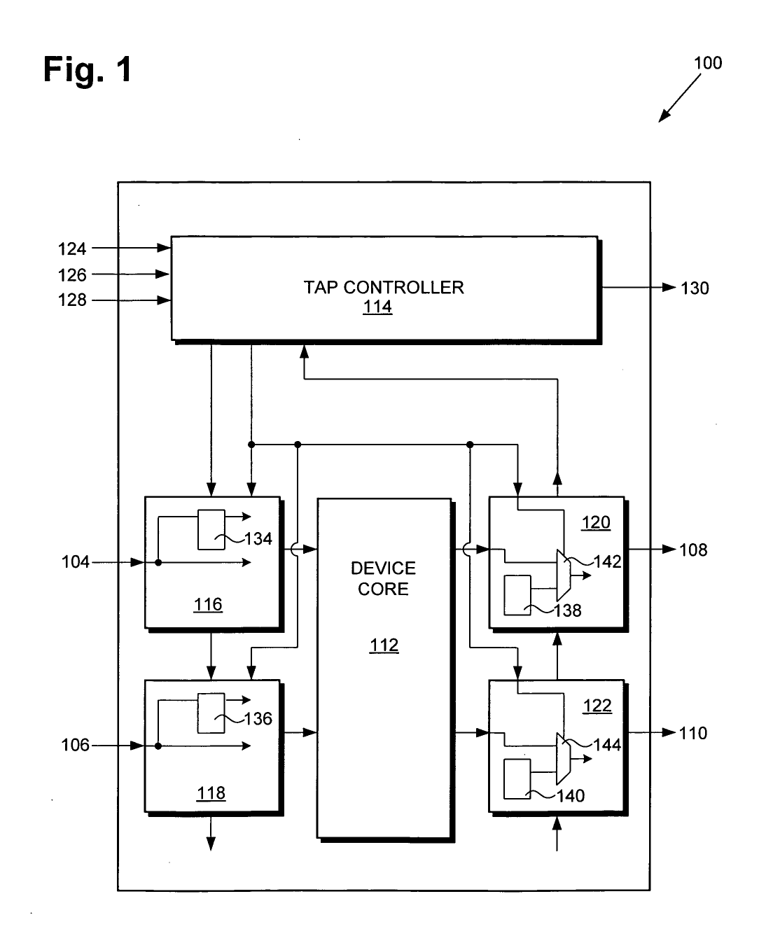

FIG. 1 is a schematic diagram illustrating semiconductor device 100 including a number of device input pins or input ports, that are also referred to as “input points” in the present application. Semiconductor device 100 also includes a number of device output pins or output ports, that are also referred to as “output points” in the present application. In particular, input points 104 and 106 and output points 108 and 110 of semiconductor device 100 are shown in FIG. 1.

Exemplary semiconductor device 100 also includes a device core 112 that includes the device's internal secure data and performs the basic and essential functions of semiconductor device 100. For example, device core 112 can be a volatile or non-volatile memory array, a processor, a signal processor, a digital filter, and in general any digital or analog module that is used in modern semiconductor devices. As known in the art, a JTAG boundary scan compliant testing architecture includes, among other things, a TAP (“Test Access Port”) controller 114, input boundary scan registers 116, 118, and output boundary scan registers 120, and 122.

TAP controller 114 receives test data-in 124, test mode-select 126, and test clock 128 as inputs of semiconductor device 100, and provides test data-out 130 as an output of device 100. In one mode of operation, test data received through test data-in 124 is clocked into input boundary scan registers, such as input boundary scan registers 116 and 118. In one mode, the test data is fed to and processed by device core 112 and output from device core 112 is provided to test data-out 130 through output boundary scan registers, such as output boundary scan registers 120 and 122.

Input boundary scan registers 116 and 118 include, among other things, input capture registers 134 and 136, respectively, and output boundary scan registers 120 and 122 include, among other things, output update registers 138 and 140, respectively. Input capture registers 134 and 136, and output update registers 138 and 140 can be D-type flip-flops, for example. Output boundary scan registers 120 and 122 further include output MUXs 142 and 144, respectively which are multiplexers capable of selecting from two or more inputs depending on the specific design choices and objectives. Input boundary scan registers 116 and 118, and output boundary scan registers 120 and 122 are designed according to the IEEE 1149.1 standard, as known in the art. However, for ease of illustration, not all elements of input boundary scan registers 116 and 118, and output boundary scan registers 120 and 122 have been shown in FIG. 1.

The operation of an exemplary conventional JTAG boundary scan compliant testing architecture will now be discussed in relation to FIG. 1. In one mode of operation, input data received at input points 104 and 106 can be stored in input capture registers 134 and 136 of input boundary scan registers 116 and 118, respectively. Alternatively, test data-in 124 from TAP controller 114 can be stored in input capture registers 134 and 136 of input boundary scan registers 116 and 118, respectively. Once data has been stored in input capture registers 134 and 136, it can be provided to device core 112, which can provide outputs resulting from the normal functioning of device core 112 to output boundary scan registers 120 and 122. Outputs from device core 112 can be stored in output update registers 138 and 140 and can be eventually read at output points 108 and 110 or at test data-out 130. Thus, in this mode of operation, an unauthorized user can access the data stored in input capture registers 134 and 136 of input boundary scan registers 116 and 118, and/or the data stored in output update registers 138 and 140 of output boundary scan registers 120 and 122, thereby allowing the unauthorized user to undesirably access the internal secure data, state and/or functionality of device core 112.

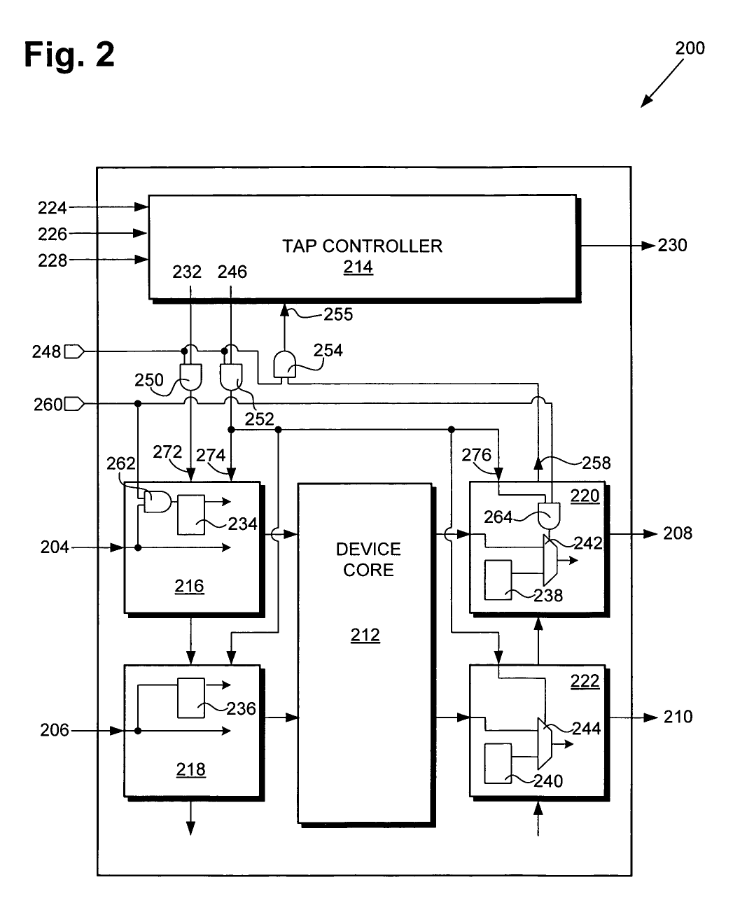

FIG. 2 is a schematic diagram illustrating semiconductor device 200 utilizing an embodiment of the invention's JTAG boundary scan compliant testing architecture. Semiconductor device 200 includes a number of device input pins or input ports, that are also referred to as “input points” in the present application. Semiconductor device 200 also includes a number of device output pins or output ports, that are also referred to as “output points” in the present application. In particular, input points 204 and 206 and output points 208 and 210 of semiconductor device 200 are exemplary input pins or ports that are shown in FIG. 2.

Exemplary semiconductor device 200 also includes device core 212 that includes the device's internal secure data and performs the basic and essential functions of semiconductor device 200. For example, device core 212 can be a volatile or non-volatile memory array, a processor, a signal processor, a digital filter, and in general any digital or analog module that is used in modern semiconductor devices. Semiconductor device 200 is a “JTAG compliant device” and, as such, the invention's JTAG boundary scan compliant testing architecture comprises, among other things, a TAP (“Test Access Port”) controller 214, input boundary scan registers 216, 218, and output boundary scan registers 220, and 222.

TAP controller 214 receives test data-in 224, test mode-select 226, and test clock 228 as inputs of semiconductor device 200, and provides test data-out 230 as an output of device 200. In one mode of operation, test data received through test data-in 224 is clocked into scan-in 272 of input boundary scan registers, such as input boundary scan registers 216 and 218, via TAP test data 232 and through AND gate 250. Multi-bit control 246, which can correspond to a plurality of control signals such as test mode-select 226 and test clock 228, is also provided, via AND gate 252 and control-in 274 and control-in 276, to input boundary scan registers 216 and 218 and output boundary scan registers 220 and 222, respectively. In one mode, the test data is fed to and processed by device core 212 and output from device core 212 is provided to test data-out 230 through scan-out 258 of output boundary scan registers, such as output boundary scan registers 220 and 222, and AND gate 254.

Input boundary scan registers 216 and 218 include, among other things, input capture registers 234 and 236, respectively, and output boundary scan registers 220 and 222 include, among other things, output update registers 238 and 240, respectively. Input capture registers 234 and 236, and output update registers 238 and 240 can be D-type flip-flops, for example. Output boundary scan registers 220 and 222 further include MUXs 242 and 244, respectively which are multiplexers capable of selecting from two or more inputs depending on the specific design choices and objectives. Input boundary scan registers 216 and 218, and output boundary scan registers 220 and 222 are designed according to the IEEE 1149.1 standard, as known in the art. However, for ease of illustration, not all elements of input boundary scan registers 216 and 218, and output boundary scan registers 220 and 222 have been shown in FIG. 2.

As part of the present innovation in preventing unauthorized users from accessing the internal secure data, and from assessing and learning about the state and/or functionality of the JTAG complaint device, the invention's JTAG boundary scan compliant testing architecture of FIG. 2 includes full JTAG disable interface 248. Full JTAG disable interface 248 can be utilized by an authorized user to completely prevent an unauthorized user from accessing the internal secure data, and from assessing and learning about the state and/or functionality of the JTAG complaint device. Such complete prevention is accomplished by preventing multi-bit control 246 from reaching input and output boundary scan registers, such as registers 216, 218, 220, and 222, and by preventing TAP controller 214 from reaching scan-in 272 of input boundary scan registers 216 and 218 and further by preventing scan-out 258 of output boundary scan registers 220 and 222 from reaching TAP controller 214.

In the present embodiment, full JTAG disable interface 248 is provided as an input to each of AND gates 250, 252, and 254. Each AND gate 250, 252, and 254 also receives input from, respectively, test data 232, multi-bit control 246, and scan-out 258, as shown in FIG. 2. In this embodiment, full JTAG disable interface 248 is activated when an authorized user sets full JTAG disable interface 248 to a logical zero. Upon activation of full JTAG disable interface 248 by an authorized user, outputs of AND gates 250, 252, and 254 are pulled to zero, regardless of the data present at test data 232, multi-bit control 246, and scan-out 258. As such, data and control communications between TAP controller 214 and the input and output boundary scan registers are effectively shut down. More specifically, scan-in 272, control-in 274 provided to input boundary scan registers, such as input boundary scan registers 216 and 218, are disabled, i.e. held at zero. Likewise, control-in 276 provided to output boundary scan registers, such as boundary scan registers 220 and 222 is disabled, i.e. held at zero. Moreover, output of AND gate 254, i.e. data-out 255, is held at zero regardless of the data present at scan-out 258 from output boundary registers, such as output boundary registers 220 and 222.

It is noted that full JTAG disable interface 248 is under command of an authorized user and can be controlled by a security module residing on or off semiconductor device 200. The security module is utilized to, for example, authenticate the identity of the authorized user and thereafter provide a capability to the authorized user to access and activate full JTAG disable interface 248, thereby disabling communications to and from TAP controller 214 as discussed above.

In the embodiment shown in FIG. 2, AND gates 250, 252, and 254 are utilized to implement the full JTAG disable mode of the present invention. However, full JTAG disable interface 248 can be used in conjunction with logic gates other than AND gates, and in a configuration different from that shown in FIG. 2. For example, NAND gates, NOR gates, and/or OR gates could be used, or in fact other combinatorial logic, or switches such as pass gates can be used to implement the concepts of the invention. If other types of logic gates or circuits are used to implement the present invention, full JTAG disable interface 248 might be activated by a value other than a logical zero, such as a logical one, or a multi-bit code or even an analog signal, so long as data and control communications between TAP controller 214 and the input and output boundary scan registers are effectively shut down by, for example, holding scan-in 272, control-in 274, control-in 276, and data-out 255 to zero.

It should be noted that because multi-bit control 246 can comprise a number of control lines reflecting, for example, the state of test mode-select 226 and/or test clock 228, AND gate 252 might have multiple inputs for receiving multiple lines from multi-bit control 246. However, when full JTAG disable interface 248 is activated (in this embodiment set to zero), control-in 274 and control-in 276 are set to zero, regardless of the data present on other inputs of AND gate 252, i.e. regardless of the data present on multiple lines received from multi-bit control 246. Thus, multi-bit control 246 in FIG. 2 is shown as a single line for ease of illustration and to preserve brevity in discussing the concepts of the present invention.

It should also be noted that when scan-in 272 and control-in 274 are held at zero, input boundary scan registers 216 and 218 are rendered ineffective, and data cannot be stored in input capture registers 234 and 236 from input points 204 and 206 or from scan-in 272. Even if data is stored in input capture registers 234 and 236, such data cannot be read out. Thus, when full JTAG disable interface 248 is activated, data is provided directly from input points 204 and 206 to device core 212, which results in normal functioning of semiconductor device 200. In other words, JTAG compliant device 200 cannot be placed in a mode that input boundary scan registers 216 and 218 can be utilized to store test data by an unauthorized user, or in a mode that an unauthorized user can access and read data stored in input boundary scan registers 216 and 218, e.g. data stored in input capture registers 234 and 236.

Likewise, when control-in 276 and data-out 255 are held at zero, output boundary scan registers 220 and 222 are rendered ineffective, and data from device core 212 or other source (such as data shifted in from the input boundary scan registers) cannot be stored in output update registers 238 and 240. Even if data is stored in output update registers 238 and 240, such data cannot be read out since control-in 276 is held at zero, ensuring, for example, that output of MUX 242 is not selected from output update register 238, and that output of MUX 244 is not selected from output update register 240. Moreover, any data present on scan-out 258 cannot be read out since data-out 255 is held at zero due to the fact that full JTAG disable interface 248 is set to zero, which results in AND gate 254 providing an output of zero at data-out 255, regardless of the data present on scan-out 258.

Thus, when full JTAG disable interface 248 is activated, data is provided directly from input points 204 and 206 to device core 212, and output of device core 212 is directly provided to output points 208 and 210, all resulting in normal use and functioning of semiconductor device 200. In other words, JTAG compliant device 200 cannot be placed in a mode that input boundary scan registers 216 and 218 and output boundary scan registers 220 and 222 can be utilized to store test data by an unauthorized user, or in a mode that an unauthorized user can access and read data stored in input boundary scan registers 216 and 218 or data stored in output boundary scan registers 220 and 222. Thus, by preventing access to input and output boundary scan registers, an unauthorized user will not be able to use the invention's JTAG boundary scan compliant testing architecture to gain access to the internal secure data, state and/or functionality of device core 212.

As a further part of the present innovation in preventing unauthorized users from accessing the internal secure data, and from assessing and learning about the state and/or functionality of the JTAG complaint device, the invention's JTAG boundary scan compliant testing architecture includes partial JTAG disable interface 260. Partial JTAG disable interface 260 can be utilized by an authorized user to prevent an unauthorized user from accessing specified areas of internal secure data, and from assessing and learning about specified areas of the state and/or functionality of the JTAG complaint device. In the present embodiment, such partial prevention is accomplished by preventing data from TAP controller 214 or pre-designated input points, such as input point 204, from being stored in pre-designated input boundary scan registers, such as input boundary scan register 216, and by preventing data stored in pre-designated output boundary scan registers, such as output boundary scan register 220, from reaching output points, such as output point 208, or from reaching TAP controller 214 through scan-out of pre-designated output boundary scan registers, such as scan-out 258 of output boundary scan register 220.

In the present embodiment, partial JTAG disable interface 260 is provided as an input to each of AND gates 262 and 264, which are added by the present invention to pre-designated input boundary scan register 216 and pre-designated output boundary scan register 220, respectively. The AND gates inside pre-designated input boundary scan registers, such as AND gate 262 in pre-designated input boundary scan register 216, also receive input from corresponding input points, such as input point 204 in case of boundary scan register 216. The AND gates inside pre-designated output boundary scan registers, such as pre-designated output boundary scan register 220, also receive input from control-in 276, as shown in FIG. 2.

In the present embodiment, partial JTAG disable interface 260 is activated when an authorized user sets partial JTAG disable interface 260 to a logical zero. Upon activation of partial JTAG disable interface 260 by an authorized user, outputs of AND gates 262 and 264 are pulled to zero, regardless of the data present at input point 204 or control-in 276. As such, data storage in input capture registers of pre-designated input boundary scan registers, such as input capture register 234, is effectively disabled and outputs of MUXs in pre-designated output boundary scan registers, such as MUX 242, are not selected from corresponding output update registers (such as output update register 238).

It is noted that, like full JTAG disable interface 248, partial JTAG disable interface 260 is under command of an authorized user and can be controlled by a security module residing on or off semiconductor device 200. The security module is utilized to, for example, authenticate the identity of the authorized user and thereafter provide a capability to the authorized user to access and activate partial JTAG disable interface 260, thereby disabling data storage in input capture registers of pre-designated input boundary registers and preventing outputs of MUXs of pre-designated output boundary registers from being selected from corresponding output update registers, as discussed above.

In the embodiment shown in FIG. 2, AND gates 262 and 264 are utilized to implement the partial JTAG disable mode of the invention. However, partial JTAG disable interface 260 can be used in conjunction with logic gates other than AND gates, and in a configuration different from that shown in FIG. 2. For example, NAND gates, NOR gates, and/or OR gates could be used, or in fact other combinatorial logic, or switches such as pass gates can be used to implement the concepts of the invention. If other types of logic gates or circuits are used to implement the present invention, partial JTAG disable interface 260 might be activated by a value other than a logical zero, such as a logical one, or a multi-bit code or even an analog signal, so long as data storage in input capture registers of pre-designated input boundary registers is effectively prevented and outputs of MUXs in pre-designated output boundary registers are not selected from corresponding output update registers.

It should also be noted that when partial JTAG disable interface 260 is activated by, for example, utilizing AND gate 262 in pre-designated input boundary scan register 216, it (i.e. input boundary scan register 216) is rendered ineffective, and data cannot be stored in input capture register 234 from input point 204 or from scan-in 272. Thus, when partial JTAG disable interface 260 is activated, data is provided directly from input point 204 to device core 212, which results in normal functioning of semiconductor device 200. In other words, JTAG compliant device 200 cannot be placed in a mode that input boundary scan register 216 can be utilized to store data by an unauthorized user.

Likewise, when partial JTAG disable interface 260 is activated by, for example, utilizing AND gate 264 in pre-designated output boundary scan register 220, it (i.e. output boundary scan register 220) is rendered ineffective, and data from output update register 238 cannot be selected for read out by MUX 242 to either output point 208 or scan-out 258. Such data cannot be read out since output of AND gate 264, which controls a select line of MUX 242, is held at zero, ensuring that MUX 242 does not select data from output update register 238.

Thus, when partial JTAG disable interface 260 is activated, data is provided directly from input point 204 to device core 212, and output of device core 212 is directly provided to output point 208, resulting in normal use and functioning of semiconductor device 200. In other words, JTAG compliant device 200 cannot be placed in a mode that input boundary scan register 216 can be utilized to store data by an unauthorized user, or in a mode that an unauthorized user can access and read data stored in output boundary scan register 220. Thus, by preventing access to pre-designated input and output boundary scan registers, an unauthorized user will not be able to use the invention's JTAG boundary scan compliant testing architecture to gain access to specified areas of the internal secure data, state and/or functionality of device core 212.

It is also noted that partial JTAG disable interface 260 may be applied only to certain pre-designated boundary scan registers. For example, partial JTAG disable interface 260 can disable use of pre-designated input boundary scan register 216 and pre-designated output boundary scan register 220 in the manner explained in one exemplary embodiment above, i.e. through use of respective AND gates 262 and 264. However, other boundary scan registers, such as input boundary scan register 218 and output boundary scan register 222 are not affected by partial JTAG disable interface 260 since they are not coupled to partial JTAG disable interface 260, nor do they feature a built-in mechanism, such as AND gates 262 and 264, to accept input from partial JTAG disable interface 260. Therefore, partial JTAG disable interface 260 permits the disabling of only pre-designated input and output boundary scan registers; hence the use of the term “partial.”

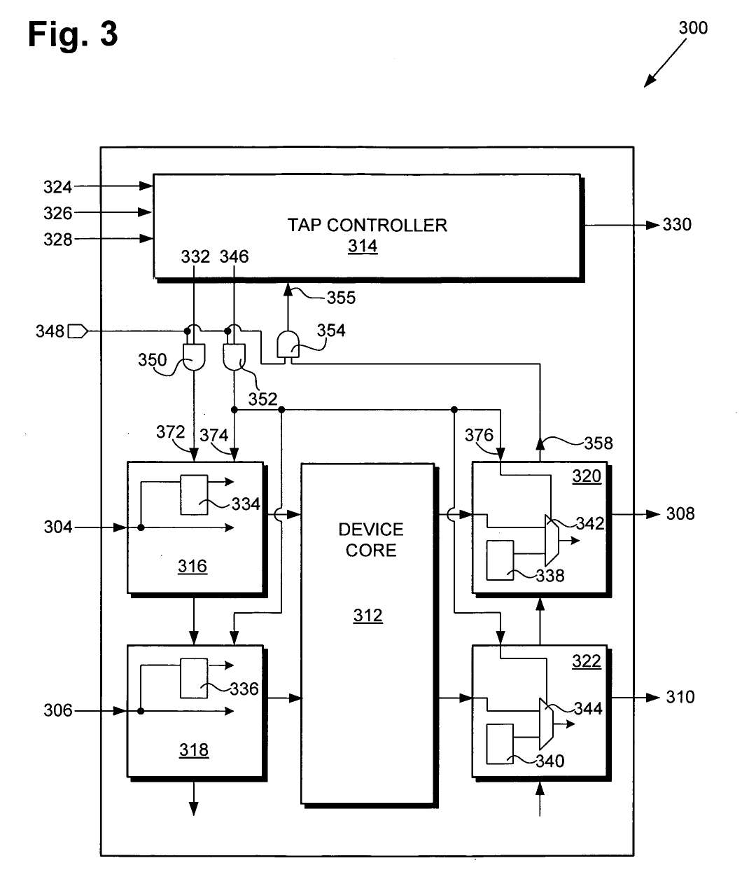

The present invention can manifestly be varied so that in one embodiment only full JTAG disable interface is utilized without the use of partial JTAG disable interface. FIG. 3 is an example of such an embodiment, where full JTAG disable interface 348 of JTAG compliant semiconductor device 300 corresponds to full JTAG disable interface 248 of JTAG compliant semiconductor device 200 in FIG. 2. In FIG. 3, AND gates 350, 352, 354 correspond respectively to AND gates 250, 252, and 254 of FIG. 2, while data-out 355 corresponds to data-out 255. Similarly, device core 312, TAP controller 314, test data-in 324, test mode-select 326, test clock 328, and test data-out 330 correspond, respectively, to device core 212, TAP controller 214, test data-in 224, test mode-select 226, test clock 228, and test data-out 230 of FIG. 2. Moreover, test data 332, mutli-bit control 346, scan-in 372, control-in 374, control-in 376, and scan-out 358 correspond, respectively, to test data 232, mutli-bit control 246, scan-in 272, control-in 274, control-in 276, and scan-out 258. Input boundary scan registers 316, 318, and input capture registers 334 and 336 correspond respectively to input boundary scan registers 216, 218, and input capture registers 234 and 236 in FIG. 2. Output boundary scan registers 320, 322, output update registers 338, 340, and MUXs 342 and 344 correspond respectively to output boundary scan registers 220, 222, output update registers 238, 240, and MUXs 242 and 244 in FIG. 2. Input points 304, 306, and output points 308 and 310, correspond respectively to input points 204, 206, and output points 208 and 210 of FIG. 2.

As shown in the embodiment of the invention's JTAG boundary scan compliant testing architecture of FIG. 3, in this embodiment only full JTAG disable interface 348 is provided and utilized in a manner similar to full JTAG disable interface 248 of FIG. 2. Thus, partial JTAG disable interface 260 of FIG. 2 is not provided, nor utilized, in this embodiment.

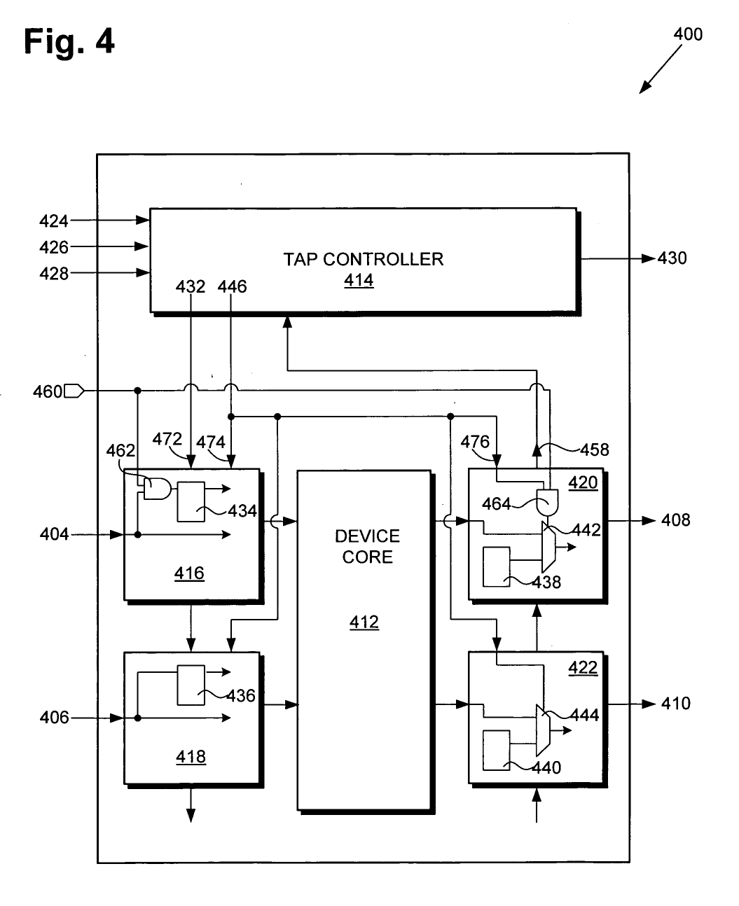

Similarly, the concepts of the present invention can be utilized so that in one embodiment only partial JTAG disable interface is utilized without the use of full JTAG disable interface. FIG. 4 is an example of such an embodiment, where partial JTAG disable interface 460 of JTAG compliant semiconductor device 400 corresponds to partial JTAG disable interface 260 of JTAG compliant semiconductor device 200 in FIG. 2. In FIG. 4, AND gates 462 and 464 correspond respectively to AND gates 262 and 264 of FIG. 2. Similarly, device core 412, TAP controller 414, test data-in 424, test mode-select 426, test clock 428, and test data-out 430 correspond, respectively, to device core 212, TAP controller 214, test data-in 224, test mode-select 226, test clock 228, and test data-out 230 of FIG. 2. Moreover, test data 432, mutli-bit control 446, scan-in 472, control-in 474, control-in 476, and scan-out 458 correspond, respectively, to test data 232, mutli-bit control 246, scan-in 272, control-in 274, control-in 276, and scan-out 258. Input boundary scan registers 416, 418, and input capture registers 434 and 436 correspond respectively to input boundary scan registers 216, 218, and input capture registers 234 and 236 in FIG. 2. Output boundary scan registers 420, 422, output update registers 438, 440, and MUXs 442 and 444 correspond respectively to output boundary scan registers 220, 222, output update registers 238, 240, and MUXs 242 and 244 in FIG. 2. Input points 404, 406, and output points 408 and 410, correspond respectively to input points 204, 206, and output points 208 and 210 of FIG. 2.

As shown in the embodiment of the invention's JTAG boundary scan compliant testing architecture of FIG. 4, in this embodiment only partial JTAG disable interface 460 is provided and utilized in a manner similar to full JTAG disable interface 260 of FIG. 2. Thus, full JTAG disable interface 248 of FIG. 2 is not provided, nor utilized, in this embodiment.

Thus, in the manner described above and through use of a full JTAG disable interface and/or a partial JTAG disable interface, various embodiments of the present invention's JTAG boundary scan compliant testing architecture prevent unauthorized users from accessing the internal secure data, and from assessing and learning about the state and/or functionality of a JTAG complaint device. From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, a JTAG boundary scan compliant testing architecture with full and partial disable has been described.

1. A JTAG boundary scan compliant testing architecture built into a semiconductor device having a plurality of input points and output points, said JTAG boundary scan compliant testing architecture comprising:
a TAP controller being capable of receiving input test data, a test mode-select, and a test clock, said JTAG boundary scan compliant testing architecture allowing an authorized user to prevent an unauthorized user from storing data into input boundary scan registers and from reading data from output boundary scan registers.

2. The JTAG boundary scan compliant testing architecture of claim 1 further allowing said authorized user to prevent said unauthorized user from reading data from said input boundary scan registers.

3. The JTAG boundary scan compliant testing architecture of claim 1 wherein a full JTAG disable interface prevents output test data provided by said TAP controller from reaching respective scan-in inputs of said input boundary scan registers.

4. The JTAG boundary scan compliant testing architecture of claim 1 wherein a full JTAG disable interface prevents said TAP controller from controlling said input boundary scan registers and said output boundary scan registers.

5. The JTAG boundary scan compliant testing architecture of claim 1 wherein a full JTAG disable interface prevents data provided by said output boundary scan registers from reaching said TAP controller.

6. The JTAG boundary scan compliant testing architecture of claim 1 wherein a full JTAG disable interface prevents data provided by said plurality of input points to said input boundary scan registers from being accessed by said unauthorized user.

7. The JTAG boundary scan compliant testing architecture of claim 1 wherein a full JTAG disable interface prevents data from being read from respective output update registers of said output boundary scan registers.

8. The JTAG boundary scan compliant testing architecture of claim 1 wherein a full JTAG disable interface prevents data from being stored in respective input capture registers of said input boundary scan registers.

9. The JTAG boundary scan compliant testing architecture of claim 1 wherein a full JTAG disable interface prevents data from being read from respective input capture registers of said input boundary scan registers.

10. The JTAG boundary scan compliant testing architecture of claim 1 wherein a full JTAG disable interface and control signals from said TAP controller are logically combined so that activating said full JTAG disable interface prevents said control signals from reaching said input and output boundary scan registers.

11. The JTAG boundary scan compliant testing architecture of claim 1 wherein a full JTAG disable interface and output test data provided by said TAP controller are logically combined so that activating said full JTAG disable interface prevents said output test data from reaching respective scan-in inputs of said input boundary scan registers.

12. The JTAG boundary scan compliant testing architecture of claim 1 wherein a full JTAG disable interface and scan-out data provided by said output boundary scan registers are logically combined so that activating said full JTAG disable interface prevents data provided by said output boundary scan registers from reaching said TAP controller.

13. A JTAG boundary scan compliant testing architecture built into a semiconductor device having an input point and an output point, said JTAG boundary scan compliant testing architecture comprising:
a TAP controller being capable of receiving input test data, a test mode-select, and a test clock, said JTAG boundary scan compliant testing architecture allowing an authorized user to prevent an unauthorized user from storing data into a pre-designated input boundary scan register.

14. The JTAG boundary scan compliant testing architecture of claim 13 further allowing said authorized user to prevent said unauthorized user from reading data from a pre-designated output boundary scan register.

15. The JTAG boundary scan compliant testing architecture of claim 13 wherein a partial JTAG disable interface prevents data provided by said input point to be stored in said pre-designated input boundary scan register.

16. The JTAG boundary scan compliant testing architecture of claim 15 wherein said partial JTAG disable interface prevents said data provided by said input point to be stored in an input capture register of said pre-designated input boundary scan register.

17. The JTAG boundary scan compliant testing architecture of claim 13 wherein a partial JTAG disable interface prevents data from being outputted by said pre-designated output boundary scan register at said output point.

18. The JTAG boundary scan compliant testing architecture of claim 17 wherein said partial JTAG disable interface prevents an output update register of said pre-designated output boundary scan register from outputting said data at said output point.

19. The JTAG boundary scan compliant testing architecture of claim 13 wherein a partial JTAG disable interface is logically combined with data provided by said input point to prevent storage of said data in said pre-designated input boundary scan register.

20. The JTAG boundary scan compliant testing architecture of claim 13 wherein a partial JTAG disable interface is logically combined with control signals from said TAP controller to prevent data from being outputted by said pre-designated output boundary scan register at said output point.
